(19) United States
(12) Patent Application Publication
(10) Pub. No.: US 2017/0133562 A1
(43) Pub. Date: May 11, 2017

(54) PACKAGE STRUCTURE AND METHOD FOR FABRICATING THE SAME

(71) Applicant: ACHROLUX INC., Sunnyvale, CA (US)

(72) Inventors: Peiching Ling, Sunnyvale, CA (US); Dezhong Liu, Sunnyvale, CA (US)

(21) Appl. No.: 15/340,028

(22) Filed: Nov. 1, 2016

(30) Foreign Application Priority Data
Nov. 5, 2015 (TW) 104136461

(51) Int. Cl. H01L 33/54; H01L 33/60; H01L 33/00; H01L 33/50

(52) U.S. Cl. CPC H01L 33/54; H01L 33/508; H01L 33/507; H01L 33/60; H01L 33/0095; H01L 2933/005; H01L 2933/0041; H01L 2933/0058

(57) ABSTRACT

A package structure is provided, which includes: a light emitting element having a first surface, a second surface opposite to the first surface, and a side surface adjacent to and connected with the first surface and the second surface; a fluorescent layer covering the first surface and the side surface of the light emitting element; a transparent layer covering the fluorescent layer with an inclined surface formed at an outer side of the transparent layer; and a reflective layer formed on the inclined surface and covering an outer side of the fluorescent layer. Therefore, light can be prevented from leakage from the outer side of the fluorescent layer. A method for fabricating the package structure is also provided.

### BACKGROUND

1. Technical Field

The present disclosure relates to package structures and methods for fabricating the same, and, more particularly, to a package structure capable of emitting light and a method for fabricating the same.

2. Description of Related Art

Light emitting diodes (LEDs) have advantages of long lifetime, small volume, high shock resistance and low power consumption and, therefore, have been widely applied in various electronic products to meet lighting requirements.

FIG. 1 is a schematic cross-sectional view of a conventional LED package 1. The LED package 1 has a transparent element 16, a fluorescent layer 14 bonded to the transparent element 16, a light emitting element 10 disposed on the fluorescent layer 14, and an encapsulant 12 formed on the fluorescent layer 14 and covering side surfaces of the light emitting element 10.

When the LED package is powered on and light is emitted from the light emitting element 10 and transmits through the fluorescent layer 14, the light likely leaks from sides of the fluorescent layer 14, thus leading to a significant light loss and poor lighting efficiency. The drawbacks are particularly serious when the transparent element 16 and the fluorescent layer 14 are thin (about 250 um).

Therefore, how to overcome the above-described drawbacks has become critical.

### SUMMARY

In view of the above-described drawbacks, the present disclosure provides a method for fabricating a package structure, which comprises: providing a plurality of light emitting elements and forming an encapsulant between the light emitting elements, wherein each of the light emitting elements has a first surface, a second surface opposite to the first surface, and a side surface adjacent to and connected with the first surface and the second surface, and the encapsulant is formed between the side surfaces of any adjacent two of the light emitting elements; forming a fluorescent layer on the first surfaces of the light emitting elements and the encapsulant; forming a groove in the encapsulant between any adjacent two of the light emitting elements, wherein the groove penetrates the encapsulant and the fluorescent layer; and forming a reflective layer on a wall of the groove.

In an embodiment, a transparent layer can further be bonded to the fluorescent layer, and the groove can further extend to the transparent layer.

In an embodiment, a singulation process is performed along the groove.

The present disclosure further provides a package structure, which comprises: a light emitting element having a first surface, a second surface opposite to the first surface, and a side surface adjacent to and connected with the first surface and the second surface; an encapsulant formed on the side surface of the light emitting element; a fluorescent layer formed on the first surface of the light emitting element and the encapsulant, wherein sides of the encapsulant and the fluorescent layer constitute an inclined surface; and a reflective layer formed on the inclined surface and covering the side of the fluorescent layer.

In an embodiment, the package structure further comprises a transparent layer bonded to the fluorescent layer.

In an embodiment, the encapsulant can be made of a transparent material, and the reflective layer can be made of metal or white glue.

The present disclosure provides another method for fabricating a package structure, which comprises: providing a plurality of light emitting elements and forming a fluorescent layer on the light emitting elements, wherein each of the light emitting elements has a first surface, a second surface opposite to the first surface, and a side surface adjacent to and connected with the first surface and the second surface, and the fluorescent layer covers the first surface and the side surface of each of the light emitting elements; forming on the fluorescent layer a transparent layer that covers the fluorescent layer; forming a plurality of grooves in the transparent layer with each of the plurality of grooves formed between any adjacent two of the light emitting elements and extending in the transparent layer to a depth greater than a height of the fluorescent layer on the first surfaces of the light emitting elements; and forming a reflective layer on walls of the grooves.

In an embodiment, a singulation process is performed along the grooves.

The present disclosure provides another package structure, which comprises: a light emitting element having a first surface, a second surface opposite to the first surface, and a side surface adjacent to and connected with the first surface and the second surface; a fluorescent layer covering the first surface and the side surface of the light emitting element; a transparent layer covering the fluorescent layer with an inclined surface formed at an outer side of the transparent layer; and a reflective layer formed on the inclined surface and covering an outer side of the fluorescent layer.

In an embodiment, the reflective layer can be made of metal or white glue.

According to the present disclosure, a plurality of grooves are formed between the light emitting elements and at least penetrate the fluorescent layer (and the encapsulant) or at least extend to a depth greater than a height of the fluorescent layer on the first surfaces of the light emitting elements. As such, an inclined surface is formed at an outer side of the fluorescent layer or the transparent layer, and a reflective layer is formed on the inclined surface to cover the outer side of the fluorescent layer, thereby preventing light leakage from the outer side of the fluorescent layer. Further, inclined surfaces of the grooves facilitate light reflection from the reflective layer, and the light emitting angle can be adjusted by adjusting the depth or angle of the grooves.

### BRIEF DESCRIPTION OF DRAWINGS

FIG. 1 is a schematic cross-sectional view of a conventional LED package;

FIGS. 2A to 2E are schematic cross-sectional views showing a method for fabricating a package structure according to a first embodiment of the present disclosure, wherein FIGS. 2C′, 2D′ and 2E′ show another embodiments of FIGS. 2C, 2D and 2E, respectively; and

FIGS. 3A to 3E are schematic cross-sectional views showing a method for fabricating a package structure according to a second embodiment of the present disclosure, wherein FIGS. 3D′ and 3E′ show another embodiments of FIGS. 3D and 3E, respectively.

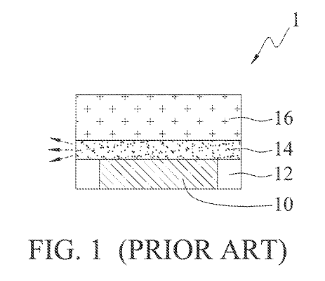

### DETAILED DESCRIPTIONS

The following illustrative embodiments are provided to illustrate the disclosure of the present disclosure, these and other advantages and effects can be apparent to those in the art after reading this specification.

It should be noted that all the drawings are not intended to limit the present disclosure. Various modifications and variations can be made without departing from the spirit of the present disclosure. Further, terms such as “first,” “second,” “on,” “a,” etc. are merely for illustrative purposes and should not be construed to limit the scope of the present disclosure.

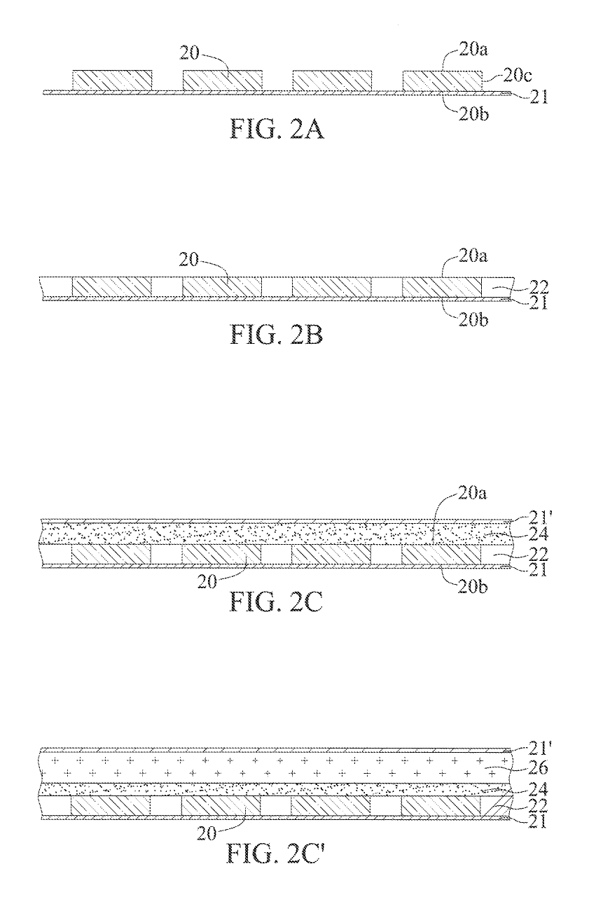

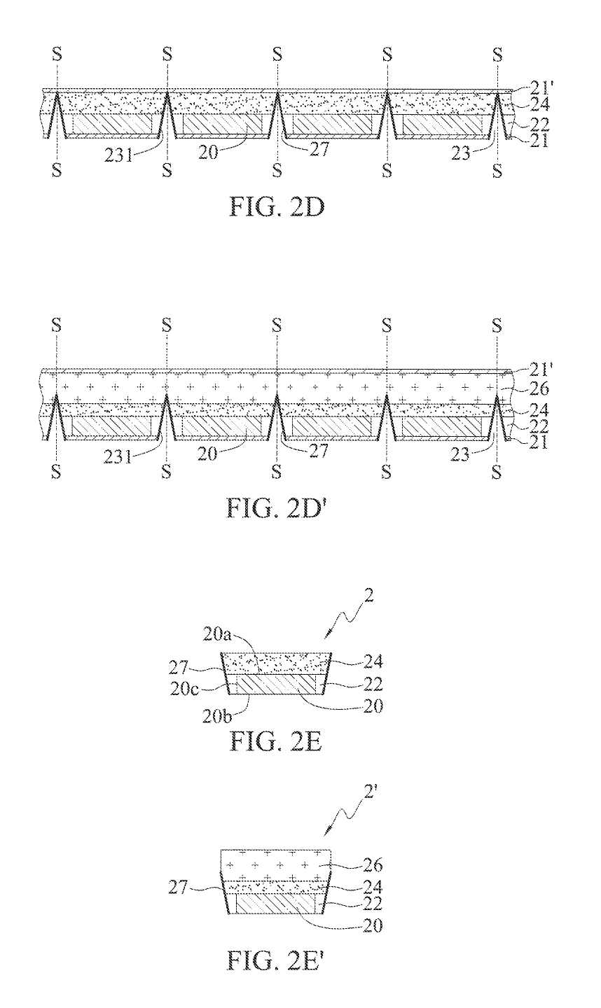

FIGS. 2A to 2E are schematic cross-sectional views showing a package structure and a method for fabricating the package structure according to a first embodiment of the present disclosure.

Referring to FIG. 2A, a plurality of light emitting elements 20 are bonded to a first release layer 21. Each of the light emitting elements 20 has a first surface 20a, a second surface 20b opposite to the first surface 20a, and a side surface 20c adjacent to and connected with the first surface 20a and the second surface 20b. In an embodiment, the light emitting elements 20 are light emitting diodes, and are bonded to the first release layer 21 via the second surfaces 20b thereof.

Referring to FIG. 2B, an encapsulant 22 is formed between the light emitting elements 20 to cover the side surfaces 20c of the light emitting elements 20, and the first surfaces 20a of the light emitting elements 20 are exposed from the encapsulant 22. In an embodiment, the encapsulant 22 is made of a transparent material such as a transparent adhesive layer (for example, transparent silicone), and the encapsulant 22 is formed by filling or molding.

Referring to FIG. 2C, a fluorescent layer 24 is formed on the first surfaces 20a of the light emitting elements 20 and the encapsulant 22. In an embodiment, fluorescent particles can be sprayed or spray-coated on the first surfaces 20a of the light emitting elements 20 and the encapsulant 22. In another embodiment, the fluorescent particles can be pre-bonded to an adhesive film and then attached to the first surfaces 20a of the light emitting elements 20 and the encapsulant 22, thus allowing the fluorescent particles to be uniformly disposed on the first surfaces 20a of the light emitting elements 20 and the encapsulant 22. Since the first surfaces 20a of the light emitting elements 20 are not covered by the encapsulant 22, when light is emitted from the first surfaces 20a of the light emitting elements 20, the light directly enters into the fluorescent layer 24 and reacts with the fluorescent particles so as to generate desired color light.

Further, an optional second release layer 21′ is formed on the fluorescent layer 24 to protect the fluorescent layer 24 from being damaged during subsequent processes.

Referring to FIG. 2D, a groove 23 is formed in the encapsulant 22 between any adjacent two of the light emitting elements 20. Each of the grooves 23 at least penetrates the encapsulant 22 and the fluorescent layer 24, and has an inverted V-shaped section. That is, sides of the encapsulant 22 and the fluorescent layer 24 constitute an inclined surface that corresponds to a wall 231 of the groove 23. Further, the light emitting angle can be adjusted by adjusting the depth and angle of the inverted V-shaped grooves 23. Furthermore, the grooves 23 can be formed by cutting.

A reflective layer 27 is formed on the walls 231 of the grooves 23, i.e., on the inclined surfaces. In an embodiment, the reflective layer 27 is a metal layer. In another embodiment, the metal layer is attached to the inclined surfaces through electroplating, deposition, coating or sputtering. In yet another embodiment, a reflective layer of, for example, white paint can be filled in the grooves 23. The first release layer 21 and the second release layer 21′ facilitate to prevent the reflective layer from being formed on the light emitting elements 20 and the fluorescent layer 24.

Referring to FIG. 2E, the first release layer 21 and the second release layer 21′ are removed to expose the second surfaces 20b of the light emitting elements 20 and the encapsulant 22, and a singulation process is performed along cutting paths S of FIG. 2D (i.e., along the grooves 23) so as to obtain a plurality of light emitting package structures 2.

FIGS. 2C′, 2D′ and 2E′ show another embodiment of FIGS. 2C, 2D and 2E. The another embodiment differs from the first embodiment in the formation of a transparent layer 26.

Referring to FIGS. 2C′, 2D′ and 2E′, a transparent layer 26 is further bonded to the fluorescent layer 24. In an embodiment, the transparent layer 26 can be made of glass, a transparent adhesive or a combination thereof. Further, the grooves 23 extend to the fluorescent layer 24 or to the fluorescent layer 24 and the transparent layer 26. According to an embodiment, a light emitting package structure 2′ is obtained.

The present disclosure further provides a package structure 2, 2′, which has: a light emitting element 20, an encapsulant 22, a fluorescent layer 24, a transparent layer 26 and a reflective layer 27.

In an embodiment, the light emitting element 20 is a light emitting diode, which has a first surface 20a, a second surface 20b opposite to the first surface 20a, and a side surface 20c adjacent to and connected with the first surface 20a and the second surface 20b. The encapsulant 22 is formed on the side surface 20c of the light emitting element 20. The fluorescent layer 24 is formed on the first surface 20a of the light emitting element 20 and the encapsulant 22. Sides of the encapsulant 22 and the fluorescent layer 24 constitute an inclined surface, and the reflective layer 27 is formed on the inclined surface and covers the side of the fluorescent layer 24. Optionally, the transparent layer 26 is further provided to cover the fluorescent layer 24.

In an embodiment, the transparent layer 26 is made of glass, a transparent adhesive or a combination thereof, and the reflective layer 27 is a metal layer.

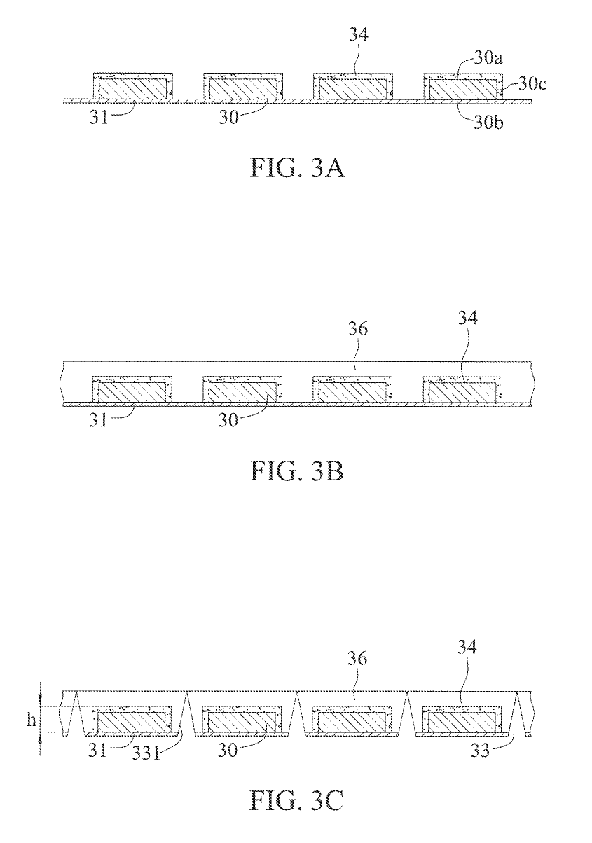

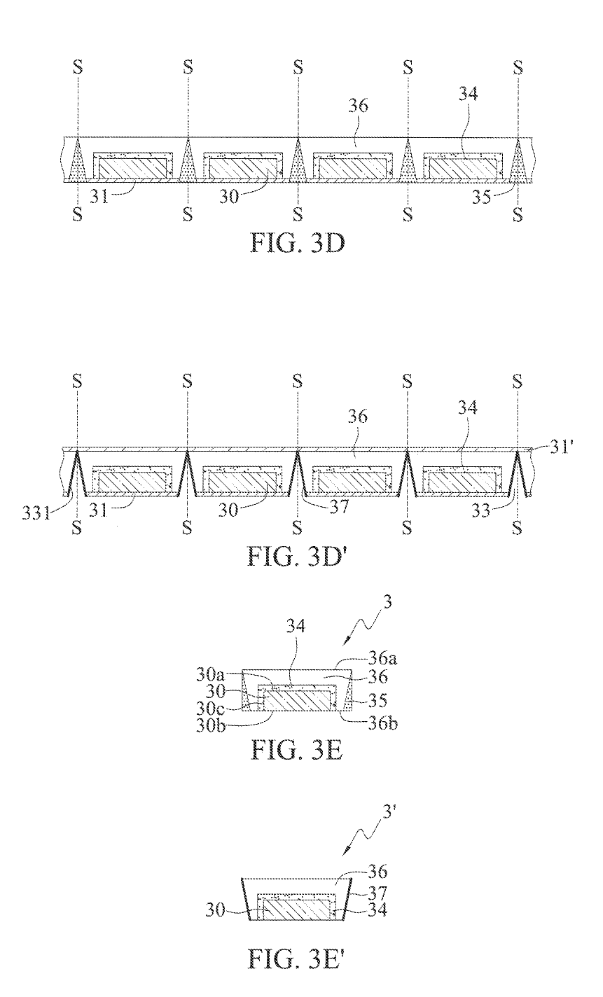

FIGS. 3A to 3E are schematic cross-sectional views showing a method for fabricating a package structure according to a second embodiment of the present disclosure. The second embodiment differs from the first embodiment in the position of the fluorescent layer.

Referring to FIG. 3A, a plurality of light emitting elements 30 are bonded to a first release layer 31. Each of the light emitting elements 30 has a first surface 30a, a second surface 30b opposite to the first surface 30a, and a side surface 30c adjacent to and connected with the first surface 30a and the second surface 30b. In an embodiment, the light emitting elements 30 are bonded to the first release layer 31 via the second surfaces 30b thereof. A fluorescent layer 34 is formed on the light emitting elements 30 and covers the first surface 30a and the side surface 30c of each of the light emitting elements 30.

Compared with the first embodiment, the second embodiment eliminates the need to forming an encapsulant between the light emitting elements.

Referring to FIG. 3B, a transparent layer 36 is formed on the first release layer 31 and the fluorescent layer 34 so as to cover the fluorescent layer 34. In an embodiment, the transparent layer 36 is made of, for example, a transparent adhesive.

Referring to FIG. 3C, a plurality of grooves 33 are formed in the transparent layer 36 between the light emitting elements 30 and at least extend to a depth above a height h of the fluorescent layer 34 on the first surfaces of the light emitting elements. In an embodiment, the grooves 33 are formed by cutting the transparent layer 36. Referring to the drawings, each of the grooves 33 has an inverted V-shape section. That is, an inclined surface is formed at an outer side of the transparent layer 36 that covers a corresponding one of the light emitting elements 30. The inclined surface corresponds to a wall 331 of the groove 33.

Referring to FIG. 3D, a reflective layer 35 is formed on the walls 331 of the grooves 33. In an embodiment, the reflective layer 35 is made of white paint, and the grooves 33 are filled with the white paint.

Referring to FIG. 3E, a singulation process is performed along cutting paths S of FIG. 3D, and the first release layer 31 is removed to expose the second surfaces 30b of the light emitting elements 30, the fluorescent layer 34 and the transparent layer 36, thereby obtaining a plurality of light emitting package structures 3.

FIGS. 3D′ and 3E′ show another embodiment of FIGS. 3D and 3E. The another embodiment differs from the second embodiment in the material and formation of the reflective layer 37.

Referring to FIGS. 3D′ and 3E′, a plurality of grooves 33 are formed in the transparent layer 36 between the light emitting elements 30, and a reflective layer 37 is formed on the walls 331 of the grooves 33. In an embodiment, the reflective layer 37 is a metal layer. In another embodiment, the metal layer is attached to the inclined surfaces of the grooves 33 through electroplating, deposition, coating or sputtering. A second release layer 31′ can be formed on the transparent layer 36 so as to protect the transparent layer 36 during the formation of the reflective layer 37. The first release layer 31 and the second release layer 31′ are removed, and a singulation process is performed along cutting paths S (i.e., along the grooves 33) of FIG. 3D′ so as to obtain a plurality of light emitting package structures 3′.

The present disclosure further provides a package structure 3, 3′, which has: a light emitting element 30, a fluorescent layer 34, a transparent layer 36 and a reflective layer 35, 37.

In an embodiment, the light emitting element 30 is a light emitting diode, which has a first surface 30a, a second surface 30b opposite to the first surface 30a, and a side surface 30c adjacent to and connected with the first surface 30a and the second surface 30b. The fluorescent layer 34 covers the first surface 30a and the side surface 30c of the light emitting element 30.

The transparent layer 36 covers the fluorescent layer 34. The transparent layer 36 has a first side 36a and a second side 36b opposite to the first side 36a. The second side 36b of the transparent layer 36 is coplanar with the second surface 30b of the light emitting element 30, and the area of the first side 36a of the transparent layer 36 is greater than the area of the second side 36b of the transparent layer 36. Therefore, an inclined surface is formed at an outer side of the transparent layer 36. In an embodiment, the transparent layer 36 is made of a transparent adhesive.

The reflective layer 35, 37 is formed on the inclined surface and covers an outer side of the fluorescent layer 34. In an embodiment, the reflective layer 35 is made of white paint. In another embodiment, the reflective layer 37 is a metal layer.

According to the present disclosure, a plurality of grooves are formed between the light emitting elements and at least penetrate the fluorescent layer (and the encapsulant) or at least extend to a depth above a height of the fluorescent layer on the first surfaces of the light emitting elements. As such, an inclined surface is formed at an outer side of the fluorescent layer or the transparent layer, and a reflective layer is formed on the inclined surface to cover the outer side of the fluorescent layer, thereby preventing light leakage from the outer side of the fluorescent layer. Further, inclined surfaces of the grooves facilitate light reflection from the reflective layer, and the light emitting angle can be adjusted by adjusting the depth or angle of the grooves.

The above-described descriptions of the detailed embodiments are only to illustrate the implementation according to the present disclosure, and it is not to limit the scope of the present disclosure. Accordingly, all modifications and variations completed by those with ordinary skill in the art should fall within the scope of present disclosure defined by the appended claims.

What is claimed is:

1. A method for fabricating a package structure, comprising:
providing a plurality of light emitting elements each having a first surface, a second surface opposite to the first surface, and a side surface adjacent to and connected with the first surface and the second surface;
forming an encapsulant between the side surfaces of any adjacent two of the light emitting elements;
forming a fluorescent layer on the first surfaces of the light emitting elements and the encapsulant;
forming a plurality of grooves in the encapsulant with each of the plurality of grooves formed between any adjacent two of the light emitting elements and penetrating the encapsulant and the fluorescent layer; and
forming a reflective layer on walls of the grooves.

2. The method of claim 1, further comprising bonding a transparent layer to the fluorescent layer.

3. The method of claim 2, wherein the groove further extends to the transparent layer.

4. The method of claim 1, further comprising performing a singulation process along the grooves.

5. The method of claim 1, wherein the encapsulant is made of a transparent material.

6. The method of claim 1, wherein the reflective layer is made of metal or white glue.

7. A package structure, comprising:
a light emitting element having a first surface, a second surface opposite to the first surface, and a side surface adjacent to and connected with the first surface and the second surface;
an encapsulant formed on the side surface of the light emitting element;
a fluorescent layer formed on the first surface of the light emitting element and the encapsulant, wherein sides of the encapsulant and the fluorescent layer constitute an inclined surface; and
a reflective layer formed on the inclined surface and covering the side of the fluorescent layer.

8. The package structure of claim 7, further comprising a transparent layer bonded to the fluorescent layer.

9. The package structure of claim 7, wherein the encapsulant is made of a transparent material.

10. The package structure of claim 7, wherein the reflective layer is made of metal or white glue.

11. A package structure, comprising:
a light emitting element having a first surface, a second surface opposite to the first surface, and a side surface adjacent to and connected with the first surface and the second surface;
a fluorescent layer covering the first surface and the side surface of the light emitting element;
a transparent layer covering the fluorescent layer with an inclined surface formed at an outer side of the transparent layer; and
a reflective layer formed on the inclined surface and covering an outer side of the fluorescent layer.

12. The package structure of claim 11, wherein the reflective layer is made of metal or white glue.
